(19) United States
(12) Patent Application Publication
(10) Pub. No.: US 2008/0186787 A1
(43) Pub. Date: Aug. 7, 2008

(54) STORAGE DEVICE

(75) Inventors: Isao AKIMA, Ogaki (JP); Jinichi NAKAMURA, Matsumoto (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/023,138

(22) Filed: Jan. 31, 2008

(30) Foreign Application Priority Data
Feb. 5, 2007 (JP) 2007-025152
Aug. 3, 2007 (JP) 2007-202618

(51) Int. Cl. G11C 7/00; G11C 8/00

(52) U.S. Cl. 365/210.15; 365/230.01

(57) ABSTRACT

A storage device includes: a ferroelectric memory that temporarily stores data, wherein the ferroelectric memory stores an error correction code that is used for verifying the data by correcting errors possibly occurring on the data stored; a storage medium that has a plurality of storage regions and continually stores the data in one of the plurality of storage regions; and a control section that (1) writes the data and the error correction code to the ferroelectric memory, (2) writes the data written in the ferroelectric memory to one of the storage regions in the storage medium, (3) compares the data that is written in the ferroelectric memory and has been verified by using the error correction code written in the ferroelectric memory with the data written to the one of the storage regions in the storage medium, and (4) rewrites the data that has been verified to another one of the storage regions in the storage medium when both of the data do not match each other.

The entire disclosure of Japanese Patent Application Nos: 2007-025152, filed Feb. 5, 2007 and 2007-202618, filed Aug. 3, 2007 are expressly incorporated by reference herein.

### BACKGROUND

1. Technical Field

The invention relates to storage devices having a storage section comprised of a storage medium, such as, for example, a hard disk drive (HDD) and a flash memory for storing data.

2. Related Art

A storage device SD 10 in related art includes, as shown in FIG. 5A, a storage section 30 that is the storage medium described above, as well as a MPU 10 and a SRAM (Static Random Access Memory) 20.

In the storage device SD10 in related art, for caching data 40 to be written to the storage section 30, the MPU 10 writes the data 40 to the SRAM 20, prior to writing the data 40 to the storage section 30, as shown in FIG. 5 (B), whereby the data is temporarily stored in the SRAM 20.

When it is judged that the data temporarily stored in the SRAM 20 should not be continuously stored in the SRAM 20, the MPU 10 writes the data 40 stored in the SRAM 20 to one of a plurality of storage regions in the storage section 30, as shown in (C) in FIG. 5, calculates an error correction code 50 that is used for verifying the data 40 by correcting errors that could possibly occur on the data 40 while the data 40 is stored in the storage section 30, and also writes the error correction code 50 to the storage section 30.

When it becomes necessary to read out the data 40 from the storage section 30 and use the same while a program (not shown) is sequentially executed, the MPU 10 reads the data 40 and the error correction code 50 from the storage section 30, and verify the data 40 by referring to the error correction code 50.

However, in the storage device SD 10 in related art described above, when the one storage region in the storage section 30 is defective to the extent that the data 40 written to the one storage region cannot be perfectly verified even by referring to the error correction code 50, the data 40 cannot be stored in a normal state in the one storage region, which consequently causes a problem in that the MPU 10 cannot use the data 40.

### SUMMARY

In accordance with an embodiment of the present invention, a storage device includes: a ferroelectric memory that temporarily stores data, wherein the ferroelectric memory stores an error correction code that is used for verifying the data by correcting errors possibly occurring on the stored data; a storage medium that has a plurality of storage regions and continually stores the data in one of the plurality of storage regions; and a control section that (1) writes the data and the error correction code to the ferroelectric memory, (2) writes the data written in the ferroelectric memory to one of the storage regions in the storage medium, (3) compares the data written in the ferroelectric memory and verified by using the error correction code written in the ferroelectric memory with the data written to the one of the storage regions in the storage medium, and (4) rewrites the data that has been verified to another one of the storage regions in the storage medium when the two data do not match each other.

According to the storage device in accordance with the embodiment described above, the data and the error correction code are temporarily written to the ferroelectric memory. When the data written in the ferroelectric memory is written to the one storage region in the storage section, the data written in the ferroelectric memory is verified by referring to the error correction code, and the verified data is compared with the data just written to the storage section. When the two data do not match each other, the verified data is rewritten to another one of the storage regions in the storage section, whereby the data is written to a normal storage region in the storage section. Accordingly, the situation in related art, in which the data may be written to a storage region where an error cannot be corrected even with an error correction code, can be avoided. Therefore, the data described above can be used, in other words, the data can be used without an error.

In the storage device in accordance with an aspect of the embodiment described above, the ferroelectric memory may store an error correction table that stipulates a plurality of relations between a plurality of data and a plurality error correction codes for verifying the plurality of data, and the control section may obtain the error correction code corresponding to the data by referring to the error correction table based on the data.

According to the storage device in accordance with the aspect of the embodiment described above, the control section obtains the error correction code corresponding to the data by referring to the error correction table, whereby a calculation processing to obtain an error correction code is not required to be conducted, and therefore the processing load on the control section can be alleviated.

In the storage device in accordance with an aspect of the embodiment described above, the ferroelectric memory and the storage medium may be in one piece.

An electronic apparatus in accordance with an embodiment of the invention includes the storage device described above.

An electronic apparatus in accordance with an embodiment of the invention has the storage medium included in the storage device described above.

An electronic apparatus in accordance with an embodiment of the invention uses the storage device described above, thereby enabling a method of using the storage medium that does not need a redundant storage region for storing the error correction code.

A storage device in accordance with an embodiment of the invention includes: a storage section that stores first data; a ferroelectric memory that stores second data whose number of accesses is relatively high among the first data; and a control section that makes accesses, for the storage section, to third data whose number of accesses is relatively low among the first data other than the second data, and accesses, for the ferroelectric memory, to the second data.

According to the storage device in accordance with the embodiment of the invention described above, the control section makes accesses, for the storage section, to the third data whose number of accesses is relatively low, and on the other hand, makes accesses, for the ferroelectric memory that has a greater durable frequency of accesses than that of the storage section, to the second data whose number of accesses is relatively high. By this, the control section can make accesses for the ferroelectric memory to the second data, whose number of accesses is greater than the number of accesses for the storage section to the third data, with a high reliability at a level similar to that in accessing to the third data.

### BRIEF DESCRIPTION OF THE DRAWINGS

FIG. 1 shows diagrams of the structure and operations of a storage device in accordance with Embodiment Example 1 of the invention.

FIG. 2 shows diagrams of operations of the storage device in accordance with Embodiment Example 1.

FIG. 3 shows an error correction code table in accordance with Embodiment Example 1.

FIG. 4 shows a diagram of the structure of a storage device in accordance with Embodiment Example 3.

FIG. 5 shows diagrams of the structure and operations of a storage device in related art.

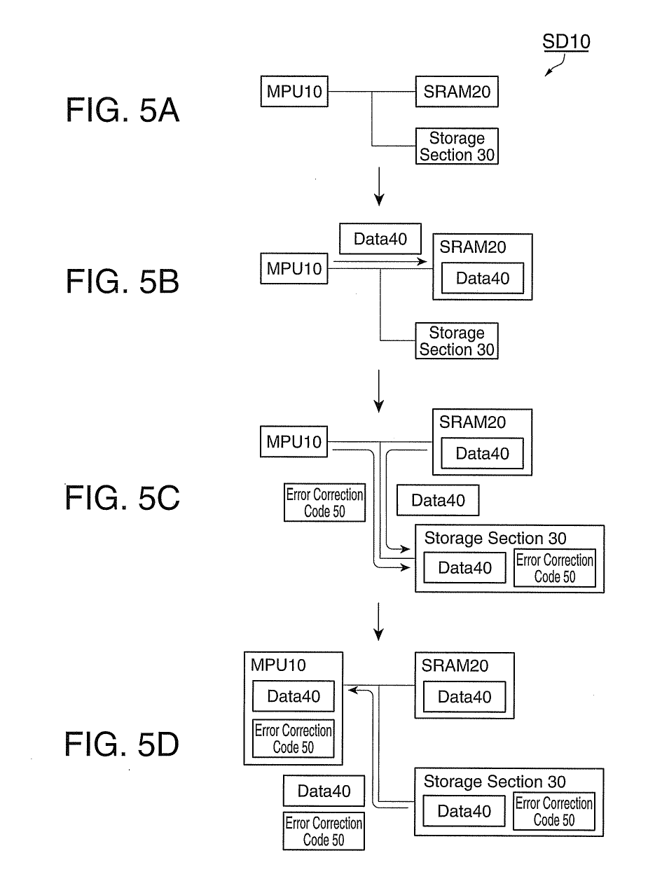

### DESCRIPTION OF EXEMPLARY EMBODIMENTS

Storage devices in accordance with preferred embodiments of the invention are described below with reference to the accompanying drawings.

### Embodiment Example 1

### Structure

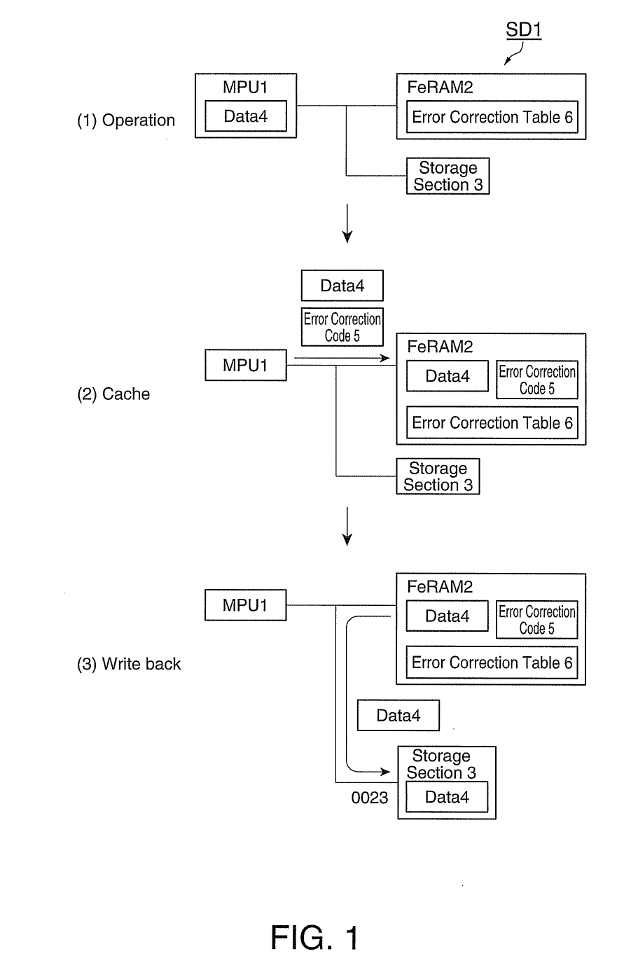

FIG. 1 shows the structure of a storage device SD1 in accordance with Embodiment Example 1. The storage device SD1 in accordance with Embodiment Example 1 includes a MPU1, a FeRAM 2, and a storage section 3, as shown in FIG. 1.

The MPU1 that is a “control section” has a function to cache data. In particular, instead of writing data 4 that is a result of processing performed by the MPU 1 to both of the FeRAM 2 and the storage section 3 (i.e., a write through operation), the MPU 1 performs a write-back operation to temporarily write (cache) only the data 4 to the FeRAM 2, and write the data 4 from the FeRAM 2 to the storage section 3, when the data 4 becomes unnecessary to be stored in the FeRAM 2.

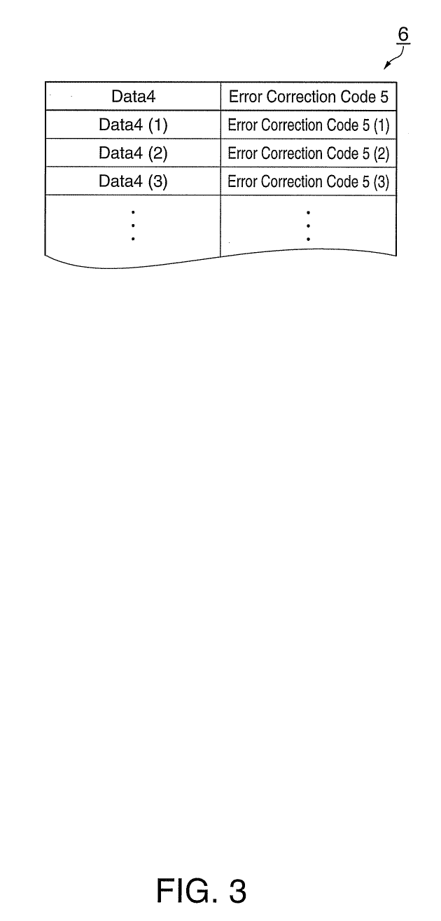

The FeRAM 2 that is a “ferroelectric memory” has nonvolatility, and even after the power supply is interrupted, continues storing data (for example, the data 4) stored before the interruption of the power supply. The FeRAM 2 also stores in advance an error correction table 6, as shown in FIG. 3, which stipulates relations between the data 4 and error correction codes 5 for correcting errors that may possibly occur while the data 4 is stored in the FeRAM 2. The error correction table 6 stipulates, for example, relations between data 4 (1) and an error correction code 5 (1) corresponding to the data 4 (1). When caching data 4 (1) that is a result of processing performed by the MPU 1 to the FeRAM 2, the MPU 1 refers to the error correction table 6, obtains an error correction code 5 (1) corresponding to the data 4 (1), and as a result writes both of the data 4 (1) and the error correction code 5 (1) to the FeRAM 2.

The storage section 3 that is a “storage medium” may be, for example, a hard disk drive (HDD) or a flash memory, and is used for continually storing data necessary for processing to be performed by the MPU 1, data that are results of processing performed by the MPU 1, and the like.

Operation

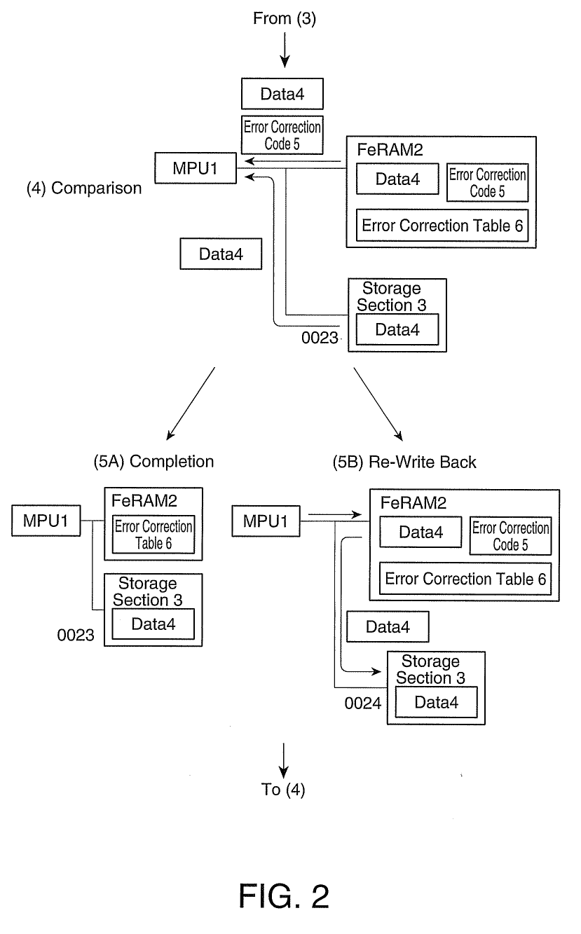

Operations of the storage device in accordance with the embodiment example are described with reference to FIG. 1 and FIG. 2.

(1) Operation: the MPU 1 performs processings such as operations by using data and the like stored in the storage section 3, as shown in (1) of FIG. 1, and obtains data 4, as a result of the processing.

(2) Cache: the MPU 1 refers to the error correction table 6 stored in the FeRAM 2 based on the data 4, thereby obtaining an error correction code 5 corresponding to the data 4. After obtaining the error correction code 5, the MPU 1 writes the data 4 and the error correction code 5 to the FeRAM 2, in other words, caches them to the FeRAM 2, as shown in (2) in FIG. 1.

(3) Write-back: when the MPU 1 judges that the data 4 should not be stored in the FeRAM 2 during the course of performing other processings such as other plural operations, for example, when the MPU 1 judges that other data should be stored in the FeRAM 2 instead of the data 4, the MPU 1 transfers only the data 4 from the FeRAM 2 to an empty storage region in the storage section 3, for example, to a storage region at an address “0023,” in other words, writes back only the data 4, as shown in (3) of FIG. 1.

(4) Comparison: as shown in (4) of FIG. 2, the MPU 1 reads the data 4 and the error correction code 5 from the FeRAM 2, and also reads the data 4 from the storage section 3, and then the MPU 1 performs a verification in which a confirmation is made by using the error correction code 5 as to whether the data 4 read from the FeRAM 2 has an error; and if there is an error, the error is corrected. After the verification, in order to confirm as to whether the content of the data 4 read from the FeRAM 2 and the content of the data 4 read from the storage section 3 match each other, the MPU 1 compares these data 4.

(5A) Completion: upon recognizing by the comparison in (4) described above that the content of the data 4 read from the FeRAM 2 and the content of the data 4 read from the storage section 3 match each other, the MPU 1 ends the processing, which results in a state as shown in (5A) of FIG. 2, where the data 4 is not stored in the FeRAM 2, but instead stored in the storage section 3.

(5B) Re-write back: upon recognizing by the comparison in (4) described above that the content of the data 4 read from the FeRAM 2 and the content of the data 4 read from the storage section 3 do no match each other, the MPU 1 judges that the storage region at the address “0023” of the storage section is not suitable for writing the data 4, and transfers again the data 4 read from the FeRAM 2 and verified as described above to another empty storage region of the storage section 3, for example, to a storage region at an address “0024,” in other words, performs a re-write back. Upon completion of the re-write back, the process returns to (4) Comparison described above, and thereafter the processes of (4) Comparison and (5B) Re-write back are repeated until the processing result reaches the state (5A) Completion.

Effect

As described above, in the storage device SD1 in accordance with Embodiment Example 1, the MPU 1 writes data 4 and an error correction code 5 corresponding to the data 4 to the FeRAM 2 in (2) Cache. In (4) Comparison, if the data 4 that is read from the FeRAM 2 and error-verified using the error correction code 5 and the data 4 read from the storage region at an address “0023” of the storage section 3 do not match each other, the data 4 after the verification is written back again to a storage region at another address “0024” of the storage section 3 in (5) Re-write back. Thereafter, the processes are similarly repeated, whereby the data 4 can be written back to a favorable storage region in the storage section 3. Therefore the data 4 can be stored in a normal empty region of the storage section 3 that is suitable for storing the data 4, and the data 4 can be continuously stored in a normal state, such that the data 4 can be used without an error.

Moreover, in the storage device SD1 in accordance with Embodiment Example 1, the MPU 1 obtains an error correction code 5 corresponding to data 4 by referring to the error correction table 6 stored in the FeRAM 2, and therefore the MPU 1 itself is not required to perform an operation to obtain the error correction code 5, unlike the related art, such that the processing load on the MPU 1 can be alleviated, compared to the related art.

Furthermore, the storage device SD1 in accordance with Embodiment Example 1 can obtain effects similar to those described above, even when the FeRAM 2 and the storage section 3 are provided in one piece, instead of being provided independently from each other. In addition, by so doing, the storage device SD 1 can be made smaller in size, compared to the structure in which they are provided independently from each other.

Also, it is possible to make it unnecessary to secure a redundant storage region for storing error correction code data in the storage section 3 that is a “storage medium” such that the memory capacity of the storage section can be more effectively utilized.

### Embodiment Example 2

Electronic apparatuses in accordance with Embodiment Example 2 of the invention are described. The electronic apparatuses in accordance with Embodiment Example 2 include a storage device SD 1 in accordance with Embodiment Example 1, and may be, for example, computers, cellular phones, digital cameras, and the like. In the electronic apparatus in accordance with Embodiment Example 2, the MPU 1 in accordance with Embodiment Example 1 performs processings similar to those described above ((4) Comparison and the like) for data 4 for processings (for example, information processing, communication processing and image processing) to be performed by the electronic apparatus, based on the error correction code 5 stored in the FeRAM 2, whereby effects similar to those described above can be obtained.

### Embodiment Example 3

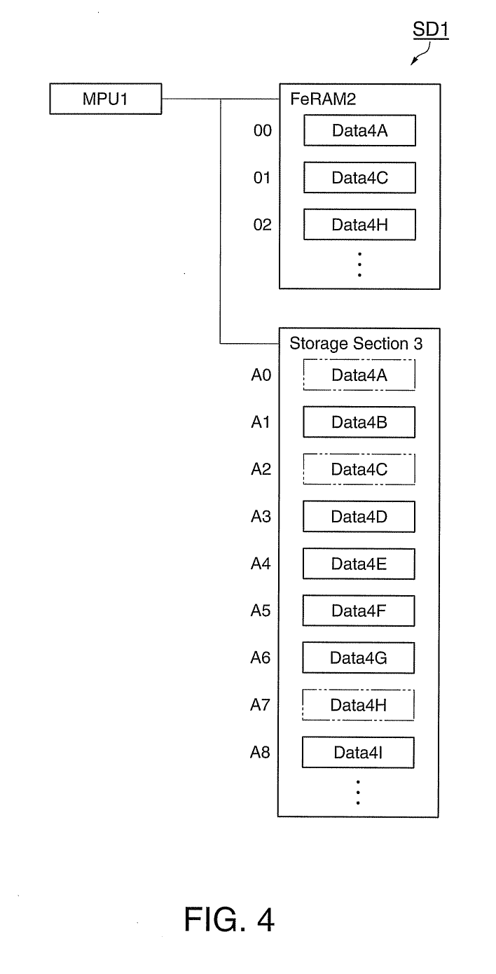

A storage device SD 1 in accordance with Embodiment Example 3 of the invention is described. The storage device SD 1 in accordance with Embodiment Example 3 includes, as shown in FIG. 4, an MPU 1, a FeRAM 2 and a storage section 3, like Embodiment Example 1. Among data 4A, 4B, 4C, . . . , etc. that should originally be stored at addresses “A0,” “A1,” “A2,” . . . , etc. in the storage section 3, data 4A, 4C and 4H stored at address “A0,” “A2” and “A7” whose number (frequency) of accesses (reading or writing) is relatively high in the past, in other words, considered based on the past record of accesses, are stored at addresses “00,” “01” and “02” of the FeRAM 2. As a result, the storage section 3 stores data other than the data 4A, 4C and 4H, in other words, data 4B, data 4D, data 4E, . . . , etc.

According to a program (not shown), the MPU 1 performs processings stipulated by the program, and during this processing, the MPU 1 makes accesses, according to the necessity, for the FeRAM 2, to the data 4A, 4C, 4H, . . . , etc., and for the storage section 3, to the data 4B, 4D, 4E, . . . , etc. The MPU 1 makes accesses for the FeRAM 2 to the data 4A, 4C, 4H, . . . , etc. more frequently than accesses for the storage section 3 to the data 4B, 4D, 4E, . . . , etc. On the other hand, the FeRAM 2 has a higher durable frequency of accesses, compared to that of the storage section 3, and in particular has an extremely high durable frequency of writings. Accordingly, the MPU 1 can make accesses for the FeRAM 2 to the data 4A, 4C, 4H, . . . , etc. with a high reliability, like accesses for the storage section 3 to the data 4B, 4D, 4E, . . . , etc.

What is claimed is:

1. A storage device comprising:
a ferroelectric memory that temporarily stores data, wherein the ferroelectric memory stores an error correction code that is used for verifying the data by correcting errors possibly occurring on the data stored;
a storage medium that has a plurality of storage regions and continually stores the data in one of the plurality of storage regions; and
a control section that
(1) writes the data and the error correction code to the ferroelectric memory,
(2) writes the data written in the ferroelectric memory to one of the storage regions in the storage medium,
(3) compares the data written in the ferroelectric memory and verified by using the error correction code written in the ferroelectric memory with the data written to the one of the storage regions in the storage medium, and
(4) rewrites the data that has been verified to another one of the storage regions in the storage medium when both of the data do not match each other.

2. A storage device according to claim 1, wherein the ferroelectric memory stores an error correction table that stipulates a plurality of relations between a plurality of data and a plurality error correction codes for verifying the plurality of data, and the control section obtains the error correction code corresponding to the data by referring to the error correction table based on the data.

3. A storage device according to claim 1, wherein the ferroelectric memory and the storage medium are in one piece.

4. An electronic apparatus comprising the storage device set forth in claim 1.

5. An electronic apparatus comprising the storage medium included in the storage device set forth in claim 1.

6. An electronic apparatus enabling a method of using the storage medium that does not need a redundant storage region for storing the error correction code by using the storage device set forth in claim 1.

7. A storage device comprising:
a storage section that stores first data;
a ferroelectric memory that stores second data whose number of accesses is relatively high among the first data; and
a control section that makes accesses for the storage section to third data whose number of accesses is relatively low among the first data other than the second data, and accesses for the ferroelectric memory to the second data.
